(19) United States
(12) Patent Application Publication
(10) Pub. No.: US 2026/0239980 A1
(43) Pub. Date: Aug. 13, 2026

(54) POWER SEMICONDUCTOR MODULE

(71) Applicants: HYUNDAI MOTOR COMPANY, SEOUL (KR); KIA CORPORATION, SEOUL (KR)

(72) Inventors: Hidekazu Tanisawa, Yokohama-Shi (JP); Ju Man Yoon, Hwaseong-si (KR)

(73) Assignees: HYUNDAI MOTOR COMPANY, SEOUL (KR); KIA CORPORATION, SEOUL (KR)

(21) Appl. No.: 19/256,925

(22) Filed: Jul. 1, 2025

(30) Foreign Application Priority Data
Feb. 10, 2025 (JP) 2025-020344

(51) Int. Cl. H10W 40/73; H10W 90/00; H10W 74/10

(52) U.S. Cl. CPC H10W 40/73; H10W 90/00; H10W 74/114; H10W 90/734

(57) ABSTRACT

A power semiconductor module with a simple structure and capable of efficiently cooling (heat dissipating) a plurality of power semiconductor devices is provided without the need for large-scale expansion. The power semiconductor module includes a plurality of semiconductor elements connected in parallel and arranged to be spaced apart from each other and a vapor chamber performing heat transport by circulation of an operating fluid. The vapor chamber covers the plurality of semiconductor devices and extends in a direction different from the direction in which the plurality of semiconductor devices are arranged.

### CROSS REFERENCE TO RELATED APPLICATIONS

This application claims benefit of priority to Japanese Patent Application No. 2025-020344 filed on February 10, 2025, in the Japanese Intellectual Property Office, the disclosure of which is incorporated herein by reference in its entirety.

### BACKGROUND

### (a) Technical Field

The present disclosure relates to a power semiconductor module having a heat dissipation structure that alleviates temperature variations during operations of a semiconductor device mounted thereon.

### (b) Description of the Related Art

In a power semiconductor module, in order to respond to a required output increase, there are cases in which a plurality of power semiconductors are connected in parallel. Even when the same semiconductor devices are connected in parallel and the thermal resistance of each semiconductor device is the same by structural design, the lengths of current paths of the semiconductor devices may be different and the current flowing in each semiconductor device varies due to a difference in inductance. This current variation causes a phenomenon in which temperatures between the semiconductor devices differ, and a semiconductor device with high temperatures is prone to thermal deterioration, which may become a weakness in reliability.

### SUMMARY

An aspect of the present disclosure is to provide a power semiconductor module in which a structure for heat dissipation is simplified by adopting a structure for alleviating the temperature difference of a plurality of semiconductor devices.

According to an aspect of the present disclosure, a power semiconductor module includes a plurality of semiconductor devices connected in parallel and arranged to be spaced apart from each other and a vapor chamber performing heat transport by circulation of an operating fluid, wherein the vapor chamber covers the plurality of semiconductor devices and extends in a direction, different from a direction in which the plurality of semiconductor devices are arranged.

### BRIEF DESCRIPTION OF THE FIGURES

The above and other aspects, features, and advantages of the present disclosure will be more clearly understood from the following detailed description, taken in conjunction with the accompanying drawings, in which:

FIG. 1 is a front view illustrating a power semiconductor module of an embodiment of the present disclosure;

FIG. 2 is a cross-sectional view taken along line A-A of FIG. 1;

FIG. 3 is an exploded perspective view of a vapor chamber;

FIG. 4 is a cross-sectional view taken along line A-A of FIG. 3;

FIG. 5 is a plan view illustrating heat transport of an embodiment;

FIG. 6 is a plan view illustrating another example of heat transport of an embodiment;

FIG. 7 is a plan view of isobaric lines representing heat transport of FIG. 5; and

FIG. 8 is a plan view of isobaric lines representing heat transport of FIG. 6.

### DETAILED DESCRIPTION

While the present disclosure may be modified in various manners and take on various alternative forms, specific embodiments thereof are illustrated in the drawings and described in detail below. However, it should be understood that there is no intent to limit the present disclosure to the particular forms disclosed, but on the contrary, the present disclosure covers all modifications, equivalents, and alternatives falling within the spirit and scope of the present disclosure.

It will be understood that although the terms “first,” “second,” etc. may be used herein to describe various elements, these elements should not be limited by these terms. These terms are only used to distinguish one element from another. For example, a first element could be termed a second element, and a second element could similarly be termed a first element without departing from the scope of the present disclosure. As used herein, the term “and/or” includes any and all combinations of one or more items listed in the associated list.

The terms used herein to describe embodiments of the present disclosure are not intended to limit the scope of the present disclosure. The articles “a” and “an” are singular in that they have a single referent, however the use of the singular form in the present document should not preclude the presence of more than one referent. In other words, elements of the present disclosure referred to in the singular may number one or more unless the context clearly indicates otherwise. It will be further understood that the terms “comprise,” “comprising,” “include,” and/or “including,” when used herein, specify the presence of stated features, numbers, steps, operations, elements, and/or components but do not preclude the presence or addition of one or more other features, numbers, steps, operations, elements, components, and/or groups thereof.

Unless defined in a different way, all the terms used herein, including technical and scientific terms, have the same meanings as understood by those skilled in the art to which the present disclosure pertains. Such terms, as defined in generally used dictionaries, should be construed to have the same meanings as those of the contexts of the related art, and unless clearly defined in the application, they should not be construed to have ideally or excessively formal meanings. In the description below, terms used in relation to directions are described based on the illustration in the drawing. Hereinafter, embodiments of the present disclosure will be described with reference to the accompanying drawings.

A power semiconductor module of the present disclosure includes a plurality of semiconductor devices connected in parallel and arranged to be spaced apart from each other and a vapor chamber covering the plurality of semiconductor devices and extending in a direction different from the direction in which the semiconductor devices are arranged.

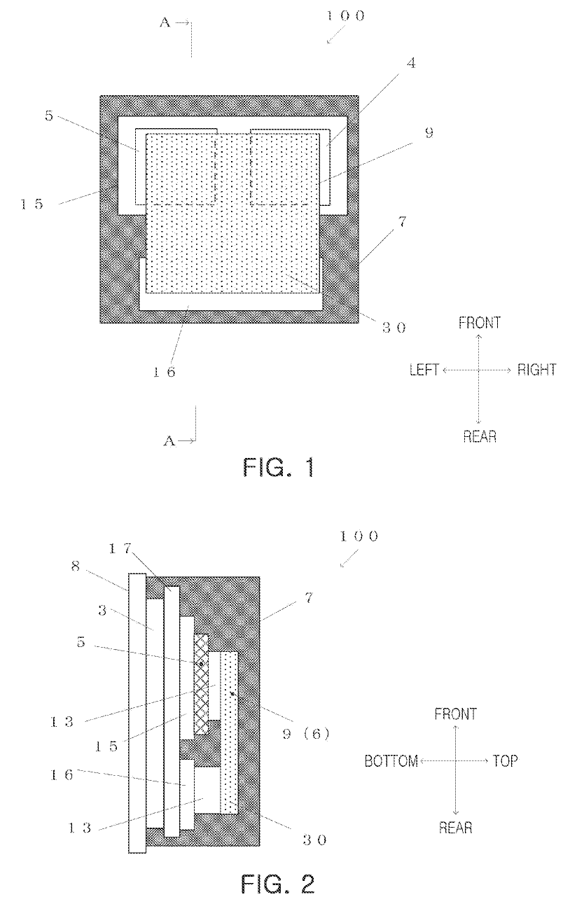

FIG. 1 is a front view of a power semiconductor module 100 of an embodiment of the present disclosure, and FIG. 2 is a cross-sectional view taken along line A-A of FIG. 1.

As illustrated in FIGS. 1 and 2, the power semiconductor module 100 includes a plurality of semiconductor devices 4 and 5 and a vapor chamber (VC) 9 spanning the semiconductor devices 4 and 5. The plurality of semiconductor devices 4 and 5 are arranged to be spaced apart from each other in a parallelly connected state. In this structure, there are cases in which the length of a current path of current flowing from a positive electrode terminal to the semiconductor device 4, passing through a power layer 15, and flowing to a negative electrode terminal is different from a length of a current path of current flowing from the positive electrode terminal to the semiconductor device 5, passing through the power layer 15, and flowing to the negative electrode terminal is different, and in this case, the inductances of the semiconductor devices 4 and 5 are different. Also, when the inductances are different, current imbalance may occur transiently, such as when a switch is turned on. At this time, the amount of heat in the semiconductor device in which a large current flows may increase, and the amount of heat in the semiconductor device in which a small current flows may decrease, and as a result, a temperature variation occurs transiently or normally. An embodiment of the present disclosure is to alleviate this temperature variation.

As illustrated in FIG. 4, the vapor chamber 9 is in the shape of a plate and has an operating fluid 19 in a flat space therein, and the operating fluid 19 performs cooling by repeatedly vaporizing by heat and liquefying by heat dissipation. The vapor chamber 9 is provided to commonly cover upper portions of the plurality of semiconductor devices 4 and 5 spaced apart from each other, and one side thereof in a direction (in the illustrated example, a direction orthogonal to the direction in which the semiconductor devices 4 and 5 are arranged), different from the direction in which the semiconductor devices 4 and 5 are arranged extends to form an extension portion 30.

The extension portion 30 of the vapor chamber 9 is thermally connected to a pattern portion connected to a cooling plate 8 on the rear of module 100. The semiconductor device 5 is bonded to a lower side of the vapor chamber 9 through the bonding layer 13. The power layer 16 is also bonded to the extension portion 30 of the vapor chamber 9 through the bonding layer 13. The lower side of the power layer 15 is a ceramic substrate 17, the lower side of the ceramic substrate 17 is a metal substrate 3, and the entirety thereof is covered with a sealing member 7. On the rear side of the metal substrate 3, a cooling plate 8 is provided. The cooling plate 8 may be a water-cooling cooler or an air-cooling cooler. Heat transferred to the extension portion 30 of the vapor chamber 9 passes through the power layer 16 and moves to the cooling plate 8.

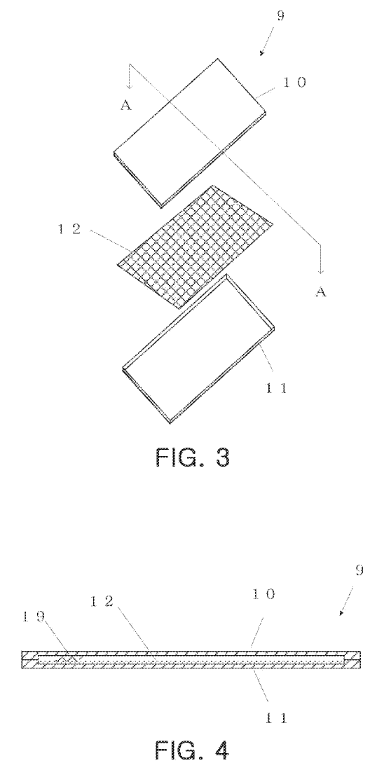

FIG. 3 is a configuration diagram of the vapor chamber 9, and FIG. 4 is a cross-sectional view taken along line A-A of FIG. 3. The vapor chamber 9 includes an upper cover 10 and a lower cover 11 and has a rectangular flat plate shape, and a wick 12 is disposed in the flat space therein, and the operating fluid 19 is injected. The operating fluid 19 is vaporized by heat from the outside, moves in a direction with low pressure, and is liquefied due to heat dissipation. The liquefied operating fluid 19 passes through the wick 12 and returns to the side where a heat source of the vapor chamber 9 is located. The vaporized operating fluid 19 may move in any direction, front, back, left, or right.

The extension portion 30 in the vapor chamber 9 extends in a direction (orthogonal direction) different from the direction in which the semiconductor devices 4 and 5 are arranged to be spaced apart from each other, and heat of the semiconductor devices 4 and 5 is transported as the operating fluid 19 moves through the extension portion 30. By this heat transport, the extension portion 30 dissipates the heat of the semiconductor devices 4 and 5, thereby balancing the heat of the semiconductor devices 4 and 5. The heat balance will be described below.

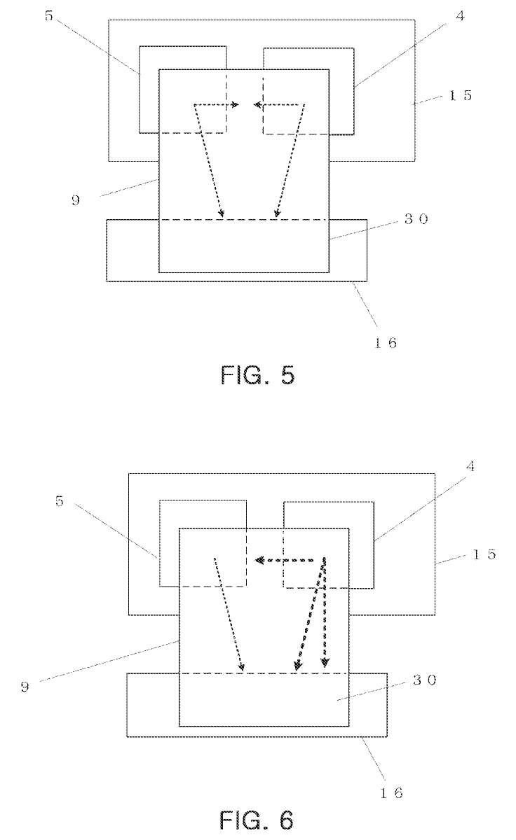

FIG. 5 illustrates heat transport by the vaporized operating fluid 19 when two semiconductor devices 4 and 5 have the same heating value. In a case in which the semiconductor devices 4 and 5 have the same heating value (i.e., the amounts of generated gas (pressure) are the same), heat transport by the gas is the same in both devices 5 and 4 as indicated by the thickness of the dashed arrows, and the heat transport is balanced in the extension portion 30.

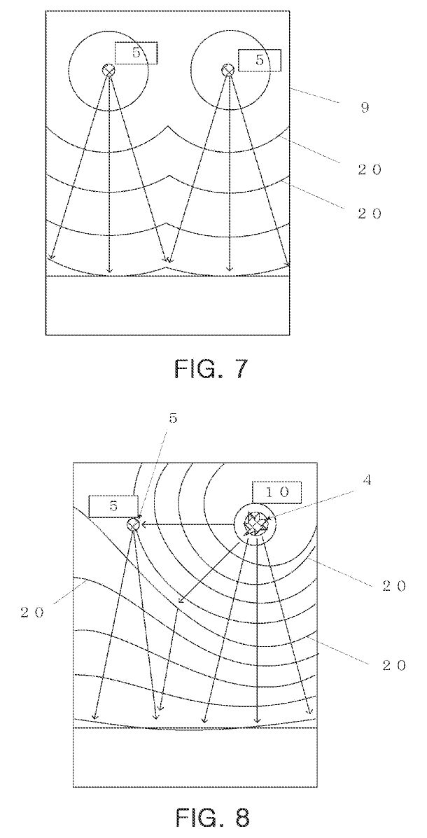

FIG. 7 corresponds to FIG. 5 and illustrates the isobaric lines 20 of the heat transport of the vaporized operating fluid 19. Heating values of the semiconductor devices 5 and 4 are both at stage “5,” and the isobaric lines 20 here propagate evenly left and right.

FIG. 6 illustrates heat transport by the vaporized operating fluid 19 when the semiconductor devices 4 and 5 have different heating values. In a case in which the heating value of the semiconductor device 5 on the other side is small, while the heating value of the semiconductor device 4 on one side is large, heat transport occurs in the amount of heat as indicated by the thickness of the broken arrow. In other words, heat is transported from the semiconductor device 4 with a large heating value to the semiconductor device 5 with a small heating value. At the same time, heat from the semiconductor devices 4 and 5 is transported by the vaporized operating fluid 19 toward the direction connected to a cooling portion of the extension portion 30. At this time, heat transport from the semiconductor device 4 with the large heating value increases. Accordingly, heat is dissipated so that a temperature difference between the semiconductor device 4 with the large heating value and the semiconductor device 5 with the small heating value is alleviated.

FIG. 8 illustrates the isobaric line 20 of heat transport corresponding to FIG. 6. When the heating value of one semiconductor device 5 is at stage “5” and the other semiconductor device 4 is at stage “10,” if a position of the extension portion 30 in which the vaporized operating fluid 19 cools and liquefies and the pressure is the lowest is set to stage “0,” the isobaric lines are drawn as illustrated. That is, the isobaric lines in the extension portion 30 of heat from the semiconductor device 4 with the large heating value become denser, the heat transport speed increases, and furthermore, the vaporized operating fluid 19 moves toward the region of the semiconductor device 5 with the small heating value. As a result, the thermal resistance from the semiconductor device 4 with the large heating value to the cooling plate 8 decreases. At this time, a cooling path on the semiconductor device 5 side with the small heating value becomes relatively smaller, so the thermal resistance increases relatively. Accordingly, heat transport is performed so that the temperature difference between the two semiconductor devices 4 and 5 is reduced, and the temperature difference between the two semiconductor devices 4 and 5 is alleviated. As a result, the temperature rise of a portion of the semiconductor devices is suppressed, thereby alleviating reliability concerns.

In the above embodiment, the case in which two semiconductor devices are arranged is described, but the present disclosure may be applied to a case in which three or more semiconductor devices are arranged and connected in parallel and spaced apart from each other. In addition, the plurality of semiconductor devices may not be of the same size but may have a structure in which semiconductor devices of different sizes are arranged to be spaced apart from each other. In addition, the areas in which the plurality of semiconductor devices contact the vapor chamber may not be the same, but the plurality of semiconductor devices may contact different areas.

As described above, in an embodiment of the present disclosure, even if the heating values of the plurality of arranged semiconductor devices are equal or different, the temperature difference deviation between the semiconductor devices is alleviated by the mechanism of heat transport by gas, which is a characteristic of the vapor chamber 9, and heat is dissipated while maintaining a balance. For this reason, the vapor chamber 9 has a simple structure, and there is no need for enlargement.

In an embodiment of the present disclosure, since the vapor chamber extends in a direction different from the direction in which the semiconductor devices are arranged, heat from the semiconductor devices may move toward the extension direction of the vapor chamber. When a temperature variation exists between the semiconductor devices, heat may be transported from a semiconductor device with a high temperature to a semiconductor device with a low temperature. Even when heat is transported from the semiconductor device with a high temperature in the extension direction of the vapor chamber, the vapor pressure is higher than the vapor pressure generated from the semiconductor device with a low temperature, so that heat is actively transported and the semiconductor device with a high temperature may be cooled, thereby reducing the temperature variation. For this reason, the alleviation of the temperature variation and heat dissipation by the vapor chamber with a simple structure may be achieved at the same time.

While example embodiments have been illustrated and described above, it will be apparent to those skilled in the art that modifications and variations could be made without departing from the scope of the present disclosure as defined by the appended claims.

1. A power semiconductor module comprising:
a plurality of semiconductor devices connected in parallel, and arranged spaced apart from each other in a first direction; and
a vapor chamber configured to perform heat transport by circulation of an operating fluid;
wherein a first portion of the vapor chamber covers the plurality of semiconductor devices, and wherein a second portion of the vapor chamber extends in a second direction different from the first direction.

2. The power semiconductor module of claim 1, wherein the vapor chamber comprises an upper cover, a lower cover, and a wick positioned between the upper cover and the lower cover.

3. The power semiconductor module of claim 1, wherein the operating fluid is injected into the vapor chamber.

4. The power semiconductor module of claim 3, wherein the operating fluid is vaporized by heat from an external source, is configured to move toward a region of low pressure and is liquefied as a result of heat dissipation.

5. The power semiconductor module of claim 1, wherein heat of the plurality of semiconductor devices is configured to be transported as the operating fluid moves through the second portion of the vapor chamber, and the second portion of the vapor chamber is configured to dissipate the heat of the plurality of semiconductor devices to balance the heat of the semiconductor devices.

6. The power semiconductor module of claim 1, further comprising a heat dissipation structure, wherein, when each of the plurality of semiconductor devices has different heating values, heat is transported from a first semiconductor device having a first heating value to a second semiconductor device having a second heating value, wherein the first heating value is larger than the second heating value.
